(19) United States
(12) Patent Application Publication
(10) Pub. No.: US 2024/0206151 A1
(43) Pub. Date: Jun. 20, 2024

(54) MEMORY DEVICE USING SEMICONDUCTOR ELEMENT

(71) Applicant: Unisantis Electronics Singapore Pte. Ltd., Singapore (SG)

(72) Inventors: Koji SAKUI, Tokyo (JP); Masakazu KAKUMU, Tokyo (JP); Nozomu HARADA, Tokyo (JP)

(21) Appl. No.: 18/545,216

(22) Filed: Dec. 19, 2023

(30) Foreign Application Priority Data
Dec. 20, 2022 (WO) PCT/JP2022/046891

(51) Int. Cl. H10B 12/00; G11C 11/404; G11C 11/4096

(52) U.S. Cl. CPC H10B 12/20; G11C 11/404; G11C 11/4096

(57) ABSTRACT

A memory device includes at least one memory array made up of pages and bit lines. Each page includes multiple memory cells connected to a bit line. A plate line is connected to a first gate conductor layer, a source line is connected to an n+ layer, the bit line is connected to an n+ layer, and a word line is connected to a second gate conductor layer. A write operation of holding positive hole groups near a gate insulating layer and an erase operation of removing the positive hole groups are performed by controlling voltages applied to the source line, the bit line, the word line, the plate line, and the bottom line, where the positive hole groups are generated in a channel region of a third semiconductor layer by a gate induced drain leakage current.

### CROSS-REFERENCE TO RELATED APPLICATIONS

This application claims priority to PCT/JP2022/046891, filed Dec. 20, 2022, the entire content of which is incorporated herein by reference.

### BACKGROUND OF THE INVENTION

### Field of the Invention

The present invention relates to a memory device using a semiconductor element.

### Description of the Related Art

In recent years, in LSI (large scale integration) technology development, there have been demands for greater packaging density, higher performance, lower power consumption, and higher functionality of memory elements.

With a typical planar MOS transistor, a channel extends in a horizontal direction along an upper surface of a semiconductor substrate. In contrast, a channel of an SGT extends in a direction perpendicular to an upper surface of a semiconductor substrate (see, for example, Japanese Patent Laid-Open No. 3-171768; and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Consequently, the SGT enables greater packaging density of semiconductor devices than does the planar MOS transistor. The use of the SGT as a select transistor enables high integration of a DRAM (dynamic random access memory; see, for example, H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT),” 2011 Proceeding of the European Solid-State Device Research Conference, (2011)) connected with a capacitor, a PCM (phase change memory; see, for example, H. S. Philip Wong, S. Raoux, S. Kim, Jiale Liang, J. R. Reifenberg, B. Rajendran, M. Asheghi and K. E. Goodson: “Phase Change Memory,” Proceeding of IEEE, Vol. 98, No 12, December, pp2b012b27 (2010)) connected with a variable resistance element, an RRAM (resistive random access memory; see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V,” IEDM (2007)), and an MRAM (magneto-resistive random access memory; see, for example, W. Kang, L. Zhang, J. Klein, Y. Zhang, D. Ravelosona, and W. Zhao: “Reconfigurable Codesign of STT-MRAM Under Process Variations in Deeply Scaled Technology,” IEEE Transaction on Electron Devices, pp. 1-9 (2015)) that varies resistance by changing an orientation of a magnetic spin using a current. There are also a capacitorless DRAM memory cell made up of a single MOS transistor (see M. G. Ertosun, K. Lim, C. Park, J. Oh, P. Kirsch, and K. C. Saraswat: “Novel Capacitorless Single-Transistor Charge-Trap DRAM (IT CT DRAM) Utilizing Electron,” IEEE Electron Device Letter, Vol. 31, No. 5, pp. 405-407 (2010)), a DRAM memory cell equipped with a trench for use to accumulate carriers and with two electrodes (see Md. Hasan Raza Ansari, Nupur Navlakha, Jae Yoon Lee, Seongjae Cho, “Double-Gate Junctionless IT DRAM With Physical Barriers for Retention Improvement”, IEEE Trans, on Electron Devices vol. 67, pp. 1471-1479 (2020)), and similar other memory cells. However, capacitorless DRAMs have a problem in that a sufficient voltage margin cannot be provided due to a great impact caused by coupling of a word line in a floating state to a gate electrode. Furthermore, if the substrate is completely depleted, this can produce serious adverse effects. The present application relates to a memory device using a semiconductor element that can be made up solely of a MOS transistor without a variable resistance element or a capacitor.

In a memory device, a capacitorless single-transistor DRAM (gain cell) has a problem in that there is large capacitive coupling between a word line and a body having an element in a floating state, and if potential of the word line swings during data read or write, the swings are transmitted as noise directly to the body of the semiconductor substrate. This causes problems of misreading or erroneous rewriting of stored data, making it difficult to put the capacitorless single-transistor DRAM to practical use. It is necessary to solve the above problems as well as to increase the packaging density of DRAM memory cells.

### SUMMARY OF THE INVENTION

To solve the above problem, according to a first aspect of the present invention, there is provided a memory device, in which a page is made up of a plurality of memory cells arranged in a row direction on a substrate in planar view, the plurality of memory cells are connected to a bit line disposed in a column direction, a memory cell array is made up of a plurality of the pages and a plurality of the bit lines, and the memory device is made up of at least one memory cell array, wherein: each of the memory cells contained in the respective pages includes: the substrate, a first semiconductor layer placed on the substrate, a first impurity layer placed on part of a surface of the first semiconductor layer, at least part of the first impurity layer being columnar in shape, a second semiconductor layer extending in a vertical direction by being placed in contact with a columnar part of the first impurity layer, a first insulating layer covering part of the first semiconductor layer and part of the first impurity layer, a first gate insulating layer surrounding the first impurity layer and the second semiconductor layer by being placed in contact with the first insulating layer, a first gate conductor layer placed in contact with the first insulating layer and the first gate insulating layer, a second insulating layer formed in contact with the first gate conductor layer and the first gate insulating layer, a third semiconductor layer placed in contact with the second semiconductor layer, a second gate insulating layer partially or entirely surrounding an upper part of the third semiconductor layer, a second gate conductor layer partially or entirely covering an upper part of the second gate insulating layer, and a second impurity layer and a third impurity layer placed, respectively, in contact with opposing lateral surfaces of the third semiconductor layer located on an outer side of one end of the second gate conductor layer in a horizontal direction in which the third semiconductor layer extends; the second impurity layer is connected with a source line, the third impurity layer is connected with a bit line, the second gate conductor layer is connected with a word line, and the first gate conductor layer is connected with a plate line; a page erase operation, a page write operation, and a page read operation are performed by controlling voltages applied to the source line, the bit line, the word line, and the plate line; the page erase operation involves extracting electron groups or positive hole groups whichever are majority carriers remaining in the second semiconductor layer or the third semiconductor layer by recombining the electron groups or the positive hole groups with majority carriers in the first impurity layer, the second impurity layer, and the third impurity layer; the page write operation involves an operation of generating the electron groups and the positive hole groups in the third semiconductor layer and the second semiconductor layer using a gate induced drain leakage current, an operation of removing the generated electron groups or the positive hole groups whichever are minority carriers in the third semiconductor layer and the second semiconductor layer, and an operation of causing part or all of the electron groups or the positive hole groups whichever are majority carriers in the third semiconductor layer and the second semiconductor layer to remain in the third semiconductor layer and the second semiconductor layer; and the page read operation involves determining whether the memory cell is in an erased state or a written state based on a magnitude relationship between memory cell currents flowing through the bit line and the source line of the memory cell.

According to a second aspect of the present invention, in the first aspect, the majority carriers in the third semiconductor layer and the second semiconductor layer are the positive hole groups, and the number of positive holes in the positive hole groups is larger in the written state than in the erased state.

According to a third aspect of the present invention, in the first aspect, the erased state is logical data of “0” and the written state is logical data of “1,” and the memory cell currents are larger for the logical data of “1” than for the logical data of “0” by an order of magnitude or more.

According to a fourth aspect of the present invention, in the first aspect, during data retention in the memory cell, a ground voltage or a first negative voltage is applied to the plate line.

According to a fifth aspect of the present invention, in the fourth aspect, during the data retention in the memory cell, the ground voltage is applied to the source line, the bit line, and the word line.

According to a sixth aspect of the present invention, in the first aspect, in the page erase operation, a first positive voltage is applied to the plate line.

According to a seventh aspect of the present invention, in the first aspect, in the page write operation, a second negative voltage is applied to the word line.

According to an eighth aspect of the present invention, in the first aspect, in the page write operation, a second positive voltage is applied to the bit line.

According to a ninth aspect of the present invention, in the first aspect, in the page read operation, a third positive voltage is applied to the word line and a fourth positive voltage is applied to the bit line.

According to a tenth aspect of the present invention, in the first aspect, a vertical distance from a bottom of the third semiconductor layer to an upper part of the first impurity layer is shorter than a vertical distance from the bottom of the third semiconductor layer to a bottom of the first gate conductor layer.

According to an eleventh aspect of the present invention, in the first aspect, the source line joined to the second impurity layer of the memory cell is shared with an impurity layer corresponding to the second impurity layer of an adjacent one of the memory cells.

According to a twelfth aspect of the present invention, in the first aspect, the bit line joined to the third impurity layer of the memory cell is shared with an impurity layer corresponding to the third impurity layer of an adjacent one of the memory cells.

According to a thirteenth aspect of the present invention, in the first aspect, a first negative voltage is applied to the plate line during data retention in the memory cell, a second negative voltage is applied to the word line in the page write operation, and the first negative voltage and the second negative voltage are equal in value.

According to a fourteenth aspect of the present invention, in the fourth aspect, the ground voltage is zero volts.

According to a fifteenth aspect of the present invention, in the first aspect, a bottom of the first impurity layer is located deeper than a bottom of the first insulating layer, and the first impurity layer is shared by the plurality of memory cells.

According to a sixteenth aspect of the present invention, in the first aspect, a bottom line is joined to the first impurity layer and a desired voltage is able to be applied to the bottom line.

According to a seventeenth aspect of the present invention, in the first aspect, in the page erase operation, a third negative voltage is applied to the source line and a fifth positive voltage is applied to the word line.

According to an eighteenth aspect of the present invention, in the sixteenth aspect, in the page erase operation, a fourth negative voltage is applied to the bottom line.

According to a nineteenth aspect of the present invention, in the sixteenth aspect, the source line, the word line, the plate line, and the bottom line are disposed in parallel in the row direction, making up the page, and the bit line disposed in the column direction is orthogonal to the page.

According to a twentieth aspect of the present invention, in the first aspect, in the page write operation, a DC current between the bit line and the source line is zero.

According to a twenty-first aspect of the present invention, in the first aspect, in the page erase operation, a voltage of the second semiconductor layer is boosted by capacitive coupling between the first gate conductor layer and the second semiconductor layer.

### BRIEF DESCRIPTION OF THE DRAWINGS

FIG. 1A is a sectional structure diagram of a memory device using a semiconductor element according to a first embodiment.

FIGS. 1BA, 1BB and 1BC are a plan view and sectional structure diagrams of a memory device in which memory cells shown in FIG. 1A are arranged in a 2 by 2 matrix.

FIGS. 2A, 2B, 2C and 2D are diagrams for explaining a write operation, carrier accumulation just after the operation, and a cell current of the memory device using the semiconductor element according to the first embodiment.

FIGS. 3A, 3B and 3C are diagrams for explaining positive-hole carrier accumulation, an erase operation, and a cell current of the memory device using the semiconductor element according to the first embodiment just after the write operation.

FIG. 4A is a diagram for explaining a method for operating the memory device according to the first embodiment.

FIG. 4B is a diagram for explaining the method for operating the memory device according to the first embodiment.

FIG. 4C is a diagram for explaining the method for operating the memory device according to the first embodiment.

FIG. 4D is a diagram for explaining the method for operating the memory device according to the first embodiment.

FIG. 4E is a diagram for explaining the method for operating the memory device according to the first embodiment.

FIG. 4F is a diagram for explaining the method for operating the memory device according to the first embodiment.

FIG. 4G is a diagram for explaining the method for operating the memory device according to the first embodiment.

### DETAILED DESCRIPTION OF THE PREFERRED EMBODIMENT

A structure, a drive system, and accumulated-carriers' behavior of a memory device, which uses a semiconductor element, according to the present invention will be described below with reference to the drawings.

### First Embodiment

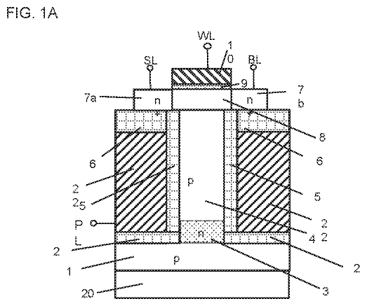

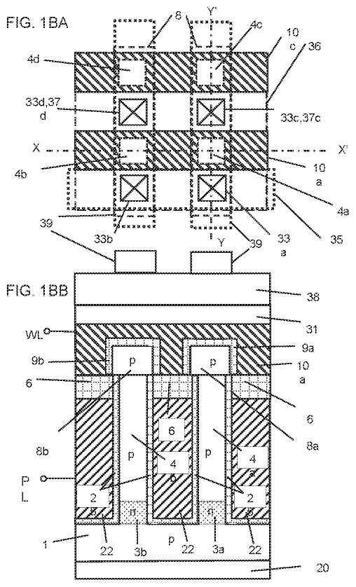

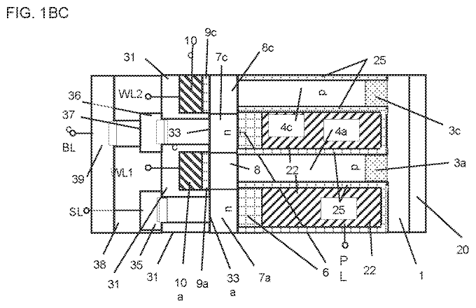

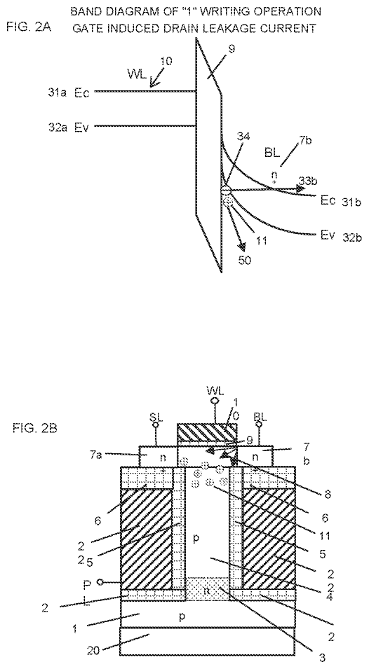

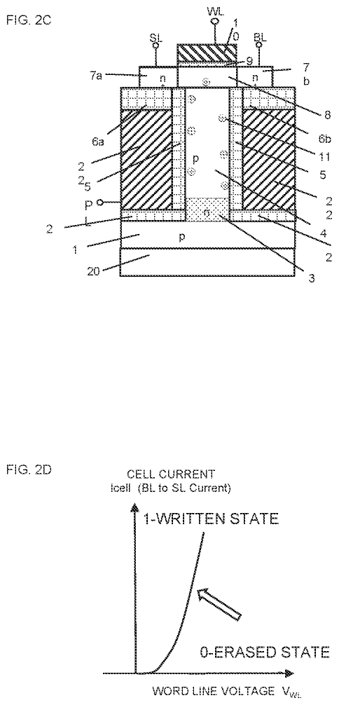

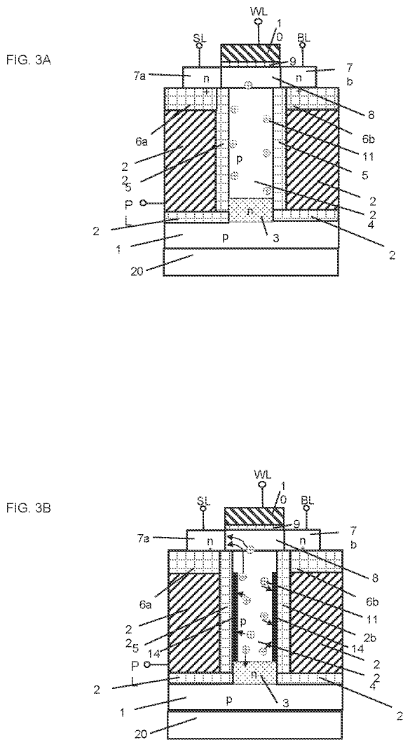

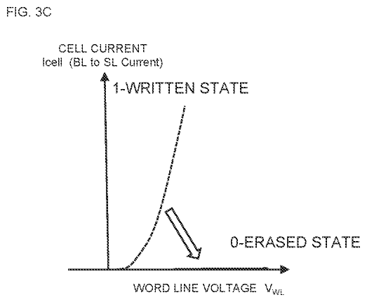

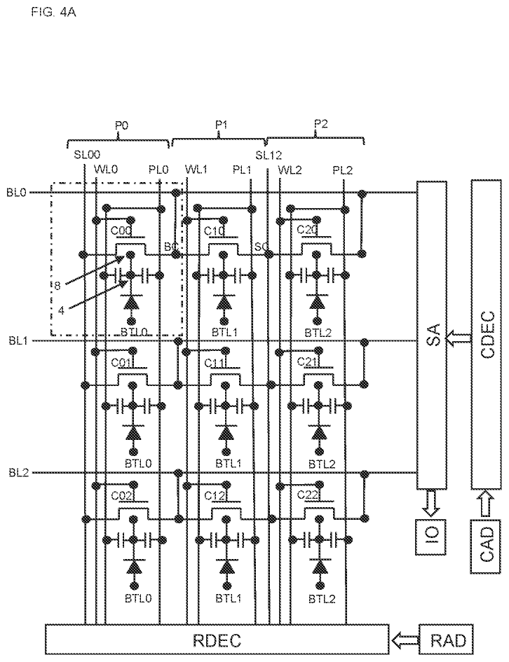

A structure and an operation mechanism of a memory cell using a semiconductor element according to a first embodiment of the present invention will be described below using FIGS. 1A to 3C. The cell structure of the memory that uses the semiconductor element according to the present embodiment will be described using FIG. 1A. The cell structure of the memory will be described in detail using FIGS. 1BA to 1BC. A data write mechanism and carrier behavior of the memory that uses the semiconductor element will be described using FIGS. 2A to 2D, and a data erase mechanism will be described using FIGS. 3A to 3C.

A vertical sectional structure of the memory cell (which is an example of a “memory cell” described in Claims) using the semiconductor element according to the first embodiment of the present invention is shown in FIG. 1A. A dynamic flash memory element will be described here by taking as an example an SGT that includes a first gate insulating layer 5 and a first gate conductor layer 22, where the first gate insulating layer 5 surrounds an entire lateral surface of a second semiconductor layer 4 erected in a vertical direction on a substrate. A silicon p-layer 1 (which is an example of a “first semiconductor layer” described in Claims) containing acceptor impurities and having a p conductivity type is placed on a substrate 20 (which is an example of a “substrate” described in Claims). A semiconductor having a columnar n-layer 3 (which is an example of a “first impurity layer” described in Claims) containing donor impurities is erected in the vertical direction on a surface of the p-layer 1. Furthermore, a columnar p-layer 4 (which is an example of a “second semiconductor layer” described in Claims) containing acceptor impurities is placed on the columnar n-layer 3. There are a first insulating layer 2 (which is an example of a “first insulating layer” described in Claims) covering part of the p-layer 1 and the n-layer 3 as well as a first gate insulating layer 5 (which is an example of a “first gate insulating layer” described in Claims) covering part of the p-layer 4. Besides, a first gate conductor layer 22 (which is an example of a “first gate conductor layer” described in Claims) is placed in contact with the first insulating layer 2 and the first gate insulating layer 5. A second insulating layer 6 (which is an example of a “second insulating layer” described in Claims) is placed in contact with the gate insulating layer 5 and the gate conductor layer 22. A p-layer 8 (which is an example of a “third semiconductor layer” described in Claims) containing acceptor impurities is placed in contact with the p-layer 4.

An n+ layer 7a (which is an example of a “second impurity layer” described in Claims) containing a high concentration of donor impurities is placed on one side of the p-layer 8. An n+ layer 7b (which is an example of a “third impurity layer” described in Claims) is placed on the side opposite the n+ layer 7a.

A second gate insulating layer 9 (which is an example of a “second gate insulating layer” described in Claims) is placed on an upper surface of the p-layer 8. The gate insulating layer 9 is placed in contact with or in proximity to the n+ layers 7a and 7b. Being in contact with the gate insulating layer 9, a second gate conductor layer 10 (which is an example of a “second gate conductor layer” described in Claims) is placed on the opposite side of the gate insulating layer 9 from the semiconductor layer 8.

This results in formation of a memory cell using a semiconductor element made up of the substrate 20, the p-layer 1, the insulating layer 2, the gate insulating layer 5, the gate conductor layer 22, the insulating layer 6, the n-layer 3, the p-layer 4, the n+ layer 7a, the n+ layer 7b, the p-layer 8, the gate insulating layer 9, and the gate conductor layer 10. The n+ layer 7a is connected to a source line SL (which is an example of a “source line” described in Claims), the n+ layer 7b is connected to a bit line BL (which is an example of a “bit line” described in Claims), the gate conductor layer 10 is connected to a word line WL (which is an example of a “word line” described in Claims), and the gate conductor layer 22 is connected to a plate line PL (which is an example of a “plate line” described in Claims). By manipulating potentials of the source line, the bit line, the plate line, and the word line, the memory is operated. Hereinafter the memory device made up of the memory cell will be referred to as a dynamic flash memory.

In the memory device according to the present embodiment, a dynamic flash memory cell is placed alone on the substrate 20 or a plurality of the dynamic flash memory cells are placed two-dimensionally on the substrate 20.

Whereas the p-layer 1 is described as being a p-type semiconductor in FIG. 1A, impurities may have concentration profiles. The impurity concentrations in the n-layer 3, the p-layer 4, and the p-layer 8 may also have profiles. The impurity concentrations and profiles in the p-layer 4 and the p-layer 8 may be set independently.

When p+ layers in which positive holes act as majority carriers are formed in place of the n+ layer 7a and the n+ layer 7b, if n-type semiconductors are used for the p-layer 1, the p-layer 4, and the p-layer 8 and a p-type semiconductor is used for the n-layer 3 and a material lower in work function than the material of the gate conductor layer 10 is used for the gate conductor layer 22, the dynamic flash memory can operate with electrons serving as carriers during writing.

Whereas in FIG. 1A, the first semiconductor layer 1 has been described as being a p-type semiconductor, even if an n-type semiconductor substrate is used as the substrate 20 and a p-well is formed thereon and the memory cell of the present invention is placed using the p-well as the first semiconductor layer 1, the memory cell will operate as a dynamic flash memory.

Whereas the insulating layer 2 and the gate insulating layer 5 are shown separately in FIG. 1A, the insulating layer 2 and the gate insulating layer 5 may be formed integrally. Hereinafter the insulating layer 2 and the gate insulating layer 5 will also be referred to together as the gate insulating layer 5.

Whereas the third semiconductor layer 8 is a p-type semiconductor in FIG. 1A, the third semiconductor layer 8 may be any of the p-type, n-type, and i-type depending on the majority carrier concentration of the p-layer 4, the thickness of the third semiconductor layer 8, the material and thickness of the gate insulating layer 9, and the material of the gate conductor layer 10.

Whereas a bottom of the p-layer 8 and an upper surface of the insulating layer 6 are illustrated as coinciding with each other in FIG. 1A, an interface between the p-layer 4 and the p-layer 8 does not need to coincide with the upper surface of the insulating layer 6 as long as the p-layer 4 and the p-layer 8 are in contact with each other and a bottom of the p-layer 4 is deeper than a bottom of the insulating layer 6.

A vertical distance from a bottom of the third semiconductor layer 8 to an upper part of the first impurity layer 3 is shorter than a vertical distance from the bottom of the third semiconductor layer 8 to a bottom of the first gate conductor layer 22.

The substrate 20 may be made of any material such as an insulator, a semiconductor, or a conductor as long as the material can support the p-layer 1.

The gate conductor layer 22 can change potential of part of the memory cell via the insulating layer 2 or the gate insulating layer 5, and may be a semiconductor layer or conductor layer doped at high concentration.

A bottom of the n-layer 3 and a bottom of the insulating layer 2, which are illustrated as coinciding with each other in FIG. 1A, do not necessarily have to coincide with each other. The n-layer 3 may spread in the p-layer 1. Besides, the n-layer 3 may be joined to an adjacent memory cell by spreading to upper part of the p-layer 1. Alternatively, the n-layer 3 may be joined to an electrode configured to apply a voltage to the n-layer 3.

FIGS. 1BA to 1BC show a memory cell array in which memory cells shown in FIG. 1A are arranged in a 2 by 2 matrix. A structure of the dynamic flash memory according to the present embodiment will be described in more detail using FIGS. 1BA to 1BC. FIG. 1BA is a plan view, FIG. 1BB is a vertical sectional structure diagram taken along line X-X′ in FIG. 1BA, and FIG. 1BC is a vertical sectional structure diagram taken along line Y-Y′ in FIG. 1BA. Same or similar components as/to those shown in FIG. 1A are denoted by reference signs containing the same numerical symbols as the corresponding components in FIG. 1A.

In FIGS. 1BA to 1BC, memory cells are provided with respective contact holes 33a to 33d in an insulating layer 31, and the memory cells are connected to a source line SL35. The source line SL35 is covered with an insulating film 38, second contact holes 37c and 37d are provided, and the memory cells are connected to a bit line BL39.

When FIG. 1A and FIGS. 1BA to 1BC are compared, components shown in FIG. 1A and FIGS. 1BA to 1BC are as follows (where the first reference signs are used in FIG. 1A and the second reference signs are used in FIGS. 1BA to 1BC): n-layer 3/n-layer 3a, p-layer 4/p-layer 4a, semiconductor layer 8/semiconductor layer 8a, n+ layer 7a/n+ layer 7a connected to SL, n+ layer 7b/n+ layer 7c connected to BL, gate insulating layer 9/gate insulating layer 9a, gate conductor layer 10/gate conductor layer 10a connected to WL, and gate conductor layer 22/gate conductor layer 22 connected to PL.

Whereas a trench is illustrated using a rectangular vertical section in FIGS. 1BA to 1BC, the trench may be trapezoidal. Besides, the first impurity layer 3 and the p-layer 4 are shown as being columnar with a quadrilateral bottom face, but may have other polygonal shapes or may be columnar with a circular bottom face.

Carrier behavior and accumulation as well as a cell current during a data write operation of the dynamic flash memory according to the first embodiment of the present invention will be described with reference to FIGS. 2A to 2D. First, the majority carriers in the n+ layer 7a and the n+ layer 7b are electrons, and poly Si containing a high concentration of acceptor impurities (hereinafter poly Si containing a high concentration of acceptor impurities will be referred to as “p+ poly”) is used, for example, for the gate conductor layer 22 connected to the plate line PL. Description will be given of a case in which poly Si containing a high concentration of donor impurities (hereinafter poly Si containing a high concentration of donor impurities will be referred to as “n+ poly”) is used for the gate conductor layer 10 connected to the word line WL and a p-type semiconductor is used for the third semiconductor layer 8. As shown in FIG. 2B, a MOSFET in the memory cell operates using the following components: the n+ layer 7a that serves as a source, the n+ layer 7b that serves as a drain, the gate insulating layer 9, the gate conductor layer 10 that serves as a gate, and the p-layer 8 that serves as a substrate. For example, 0 V is applied to the p-layer 1, for example, zero volts (0 V), which is a ground voltage, is input to the n+ layer 7a connected with the source line SL, and a first negative voltage (e.g., −1 V), which is applied during data retention of the memory cell, is applied to the gate conductor layer 22 connected with the plate line PL (where the “zero volts” is an example of “zero volts” described in Claims, the “ground voltage” is an example of a “ground voltage” described in Claims, the “first negative voltage” is an example of a “first negative voltage” described in Claims, and “during data retention” is an example of “during data retention” described in Claims). The ground voltage, (e.g., 0 V) may be input to the plate line PL. For example, 1.5 V is input to the n+ layer 7b connected with the bit line BL, and a second negative voltage (which is an example of a “second negative voltage” described in Claims) is applied to the gate conductor layer 10 connected with the word line WL. Setting the second negative voltage and the first negative voltage to an equal voltage (which is an example of “equal voltages” described in Claims) such as −1 V provides the advantage or making circuit design easier.

A mechanism of a page write operation (which is an example of a “page write operation” described in Claims) will be described using FIGS. 2A to 2D. FIG. 2A is a band diagram for explaining a mechanism of generating a gate induced drain leakage current (which is an example of a “gate induced drain leakage current” described in Claims). When a voltage applied to the n+ layer 7b, which is a third impurity layer connected with the bit line BL, is made higher than a voltage applied to the second gate conductor layer 10 connected with the word line WL, the gate induced drain leakage current (GIDL) flows. This occurs as follows: a valence band 32b and a conduction band 31b between the third semiconductor layer 8 and the n+ layer 7b, which is the third impurity layer, are bent by an intense electric field between the second gate conductor layer 10 and the n+ layer 7b, which is the third impurity layer, and consequently electron groups 34 (which are an example of “electron groups” described in Claims) tunnel to the valence band 32b and the conduction band 31b due to band-to-band tunneling 33b and flows to the n+ layer 7b, which is the third impurity layer. Positive hole groups 11 (which are an example of “positive hole groups” described in Claims) generated at this time flow to the third semiconductor layer 8 and the second semiconductor layer 4, which are floating bodies, as indicated by reference sign 50. This state is shown in FIG. 2B.

FIG. 2C shows the positive hole groups 11 in the p-layer 4 and the p-layer 8 in a written state (which are an example of “written state” described in Claims) when the word line WL, the bit line BL, and the source line SL become 0 V and the plate line PL becomes the first negative voltage just after a page write operation. The generated positive hole groups 11 are the majority carriers in the p-layer 4 and p-layer 8, but the resulting hole concentration becomes temporarily high in a region of the p-layer 8 and the resulting concentration gradient moves the positive hole groups toward the p-layer 4 through diffusion. Furthermore, because p+ poly is used for the first gate conductor layer 22 the positive hole groups are accumulated in higher concentrations in the vicinity of the first gate insulating layer 5 of the p-layer 4. As a result, the hole concentration in the p-layer 4 becomes higher than the hole concentration in the p-layer 8. Since the p-layer 4 and the p-layer 8 are electrically connected, the p-layer 8, which is a MOSFET substrate that practically has the second gate conductor layer 10, is charged to be positively biased. The positive holes in the depletion layer move toward the SL, the BL, or the n-layer 3, gradually recombining with electrons, but the threshold voltage of the MOSFET containing the second gate conductor layer 10 is reduced due to a positive substrate bias effect produced by the positive holes temporarily accumulated in the p-layer 4 and the p-layer 8. Consequently, as shown in FIG. 2D, the threshold voltage of the MOSFET containing the second gate conductor layer 10 connected with the word line WL is reduced. This written state is assigned to logical data of “1” (which is an example of “logical data of “1”” described in Claims).

Note that the conditions of the voltages applied to the bit line BL, the source line SL, the word line WL, and the plate line PL are only an example used in performing a write operation, and other conditions of the voltages that allow a write operation to be performed may be used.

With the structure according to the present embodiment, since the p-layer 8 of the MOSFET containing the second gate conductor layer 10 connected with the word line WL is electrically connected to the p-layer 4, the capacity capable of accumulating generated positive holes can be changed freely by adjusting the volume of the p-layer 4. That is, to increase retention time, for example, the p-layer 4 can be increased in depth. Therefore, it is required that the bottom of the p-layer 4 is located deeper than the bottom of the p-layer 8. Because areas placed in contact with the n-layer 3, the n+ layer 7a, and the n+ layer 7b involved in recombination with electrons can be reduced intentionally, compared to the volumes of the locations—the p-layer 4 and the p-layer 8 in this case—in which positive hole carriers are accumulated, recombination with electrons can be curbed and the retention time of accumulated positive holes can be increased. Furthermore, because the positive holes accumulated by the use of p+ poly for the gate conductor layer 22 are accumulated near an interface of the p-layer 4, which is the second semiconductor layer placed in contact with the gate insulating layer 5, and moreover, because the positive holes can be accumulated in locations away from p-n junctions that can cause electron-hole recombination, which in turn can cause data loss, i.e., away from portions in which the n+ layer 7a and the n+ layer 7b contact the p-layer 8, the positive holes can be accumulated stably. Thus, the whole substrate bias effect of the memory element is achieved on the substrate serving as the memory element, increasing the memory holding time. This expands a voltage margin in a state of being written with “logical data of “1.”

In the page write operation, since the gate induced drain leakage current is used, a DC current (which are an example of a “DC current” described in Claims) between the bit line and the source line is zero. Consequently, the page write operation can be performed at an extremely low power consumption and multi-bit memory cells can be written simultaneously.

Next, a mechanism of a page erase operation (which is an example of a “page erase operation” described in Claims) will be described using FIGS. 3A to 3C. FIG. 3A shows a state produced just after the word line WL, the bit line BL, and the source line SL become 0 V and the plate line PL becomes the ground voltage or the first negative voltage, with the positive hole groups 11 in a written state being stored in the p-layer 4 and the p-layer 8 in the previous cycle before the page erase operation. As shown in FIG. 3B, during the page erase operation, the voltage of the plate line PL is set to a first positive voltage (which is an example of a “first positive voltage” described in Claims), that is, for example, to 2 V. As a result, regardless of the value of an initial potential of the p-layer, which is the third semiconductor layer 8, capacitive coupling between the plate line PL and the second semiconductor layer 4, which is in a floating state, causes the voltages of the second semiconductor layer 4 and the p-layer to increase, where the p-layer is the third semiconductor layer 8. Consequently, a PN junction between the n+ layer 7b and the p-layer 8 becomes forward-biased, where the third semiconductor layer 8 is connected with the source line SL and the bit line BL on the n+ layer 7b, which serves as a drain. As a result, the positive hole groups 11 stored in the p-layer 4 and the p-layer 8 in the previous cycle move to the n+ layer 7a and the n+ layer 7b connected to the source line SL and the bit line BL. As a result of applying a voltage of 2 V to PL, an inversion layer 14 is formed at an interface between the gate insulating layer 5 and the p-layer 4, and comes into contact with the n-layer 3 connected to a bottom line BTL (which is an example of a “bottom line” described in Claims). Consequently, the positive holes accumulated in the p-layer 4 flow from the p-layer 4 to the n-layer 3 or the inversion layer and recombine with electrons. As a result, the hole concentrations of the p-layer 4 and the p-layer 8 are reduced with time, and the threshold voltage of the MOSFET becomes higher than in a state in which the memory cell is written with logical data of “1,” and thus the memory cell enters an erased state. Consequently, as shown in FIG. 3C, the threshold of the MOSFET containing the gate conductor layer 10 connected with the word line WL takes a value corresponding to the erased state, and the erased state of the dynamic flash memory is assigned to logical data of “0” (which is an example of “logical data of “0”” described in Claims).

With the structure according to the present embodiment, during data erasure, compared to during data accumulation, an electron-hole recombination area can be effectively increased. Therefore, logical data of “0” can be put into a stable state in a short time, improving the operating speed of the dynamic flash memory element.

Note that the conditions of voltages applied to the bit line BL, the source line SL, the word line WL, and the plate line PL are only an example used in performing a memory erase operation, and other conditions of voltages that allow a memory erase operations to be performed may be used. For example, whereas an example in which the gate conductor layer 22 is biased at 2 V has been described as an example, if for example, BL is biased at 0.2 V, SL at 0 V, and the first and second gate conductor layers at 2 V during data erasure, inversion layers in which electrons are majority carriers can be formed at an interface between the p-layer 8 and the gate insulating layer 9 and at an interface between the p-layer 4 and the gate insulating layer 2, the area of electron-hole recombination can be increased, and by passing a current in which electrons are majority carriers between BL and SL, the erase time can be further shortened intentionally.

According to the present embodiment, the p-layer 8, which is one of the components of the MOSFET that reads and writes information, is electrically connected with the p-layer 1, the n-layer 3, and the p-layer 4. Furthermore, a voltage can be applied to the gate conductor layer 22. Therefore, both in a write operation and an erase operation, unlike, for example, an SOI structure, neither the substrate bias becomes unstable in a floating state during operation of the MOSFET nor a semiconductor portion under the gate insulating layer 9 becomes completely depleted. Consequently, the threshold, drive current, and the like of the MOSFET are hardly affected by operational status. Therefore, properties of the MOSFET are such that by adjusting the thickness, impurity type, impurity concentration, and impurity profile of the p-layer 8, the impurity concentration and impurity profile of the p-layer 4, the thickness and material of the gate insulating layer 9, and work functions of the gate conductor layers 10 and 22, voltages relevant to a desired memory operation can be set in a wide range. Because components under the MOSFET are not completely depleted and the depletion layer spreads in a depth direction of the p-layer 4, coupling of a word line in a floating state to a gate electrode, which is a defect of capacitorless DRAMs, almost does not have any impact. That is, the present embodiment allows a wide margin to be provided to operating voltage of the dynamic flash memory.

In the page erase operation, large capacitive coupling (which is an example of “capacitive coupling” described in Claims) between the first gate conductor layer 22 and the second semiconductor layer 4 allows the voltage of the second semiconductor layer 4 to be boosted. As a result, PN junctions involving the second impurity layer 7a, the third impurity layer 7b, the first impurity layer 3, the second semiconductor layer 4, and the third semiconductor layer 8 can be forward-biased easily.

The present embodiment is effective in preventing malfunctions of memory cells. In memory cell operation, when voltages of a target cell are manipulated, unnecessary voltages are applied to some electrodes of cells other than the target cell in a cell array, resulting in a malfunction, which presents a big problem (for example, Takashi Ohsawa and Takeshi Hamamoto, “Floating Body Cell—a Novel Body Capacitorless DRAM Cell”, Pan Stanford Publishing (2011)). Specifically, such a malfunction involves a phenomenon in which logical data of “1” written into a memory cell is turned to logical data of “0” by another memory cell operation or logical data of “0” written into a cell is turned to logical data of “1” by another cell operation (hereinafter the phenomenon caused by such a malfunction will be referred to as a “disturbance failure”). According to the present embodiment, when logical data of “1” is originally written as data information, the quantity of accumulated holes can be increased by adjusting the depth of the p-layer 4 compared to quantity of electron-hole recombination caused by transistor operation and even under conditions in which conventional memories cause a disturbance failure, threshold fluctuations of the MOSFET are not affected much and thus the MOSFET is less prone to failure. On the other hand, when logical data of “0” is originally written as data information, even if unintended positive holes are generated by transistor operation during reading, because the positive holes diffuse quickly in the p-layer 4, if the depth of the p-layer 4 is increased similarly, the rate of change of hole concentration in the entire p-layer 4 and p-layer 8 is low and again, the threshold of the MOSFET is not affected much, and the probability of occurrence of disturbance failure can be reduced more than before. Thus, the present embodiment provides a structure resistant to disturbance failure of memory.

When data information is logical data of “0”, because the positive holes generated in the depletion layer in the memory cell during data retention and the positive holes making up the electron-hole pairs are accumulated in the p-layer 8, the logical data may turn from “0” to “1,” but with the structure according to the present invention, because a positive holes are accumulated in higher concentrations in the p-layer 4, changes in the hole concentration in the p-layer 8 just under the MOSFET is not affected much, and thus logical data of “0” information can be held stably.

As can be seen from the structure shown in FIG. 1, an element structure made up of the p-layer 8, the n+ layers 7a and 7b, the gate insulating layer 9, and the gate conductor layer 10 can be formed not only of the present memory cell, but also in common with a MOS circuit containing a typical CMOS structure other than the present structure. Thus, the present memory cell can be easily combined with conventional CMOS circuits.

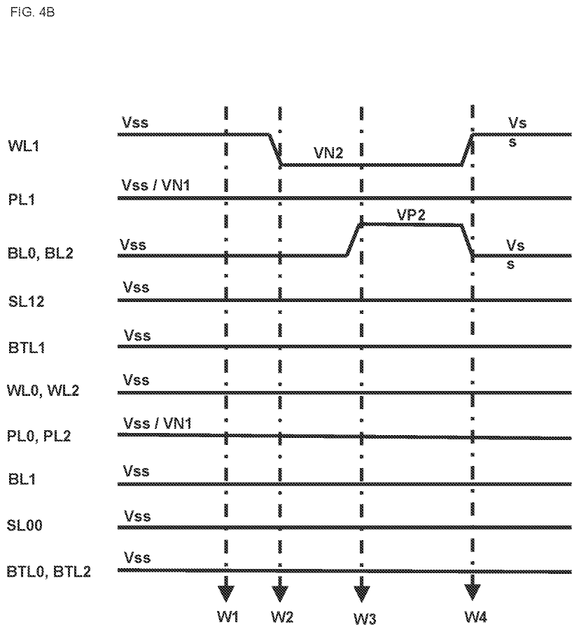

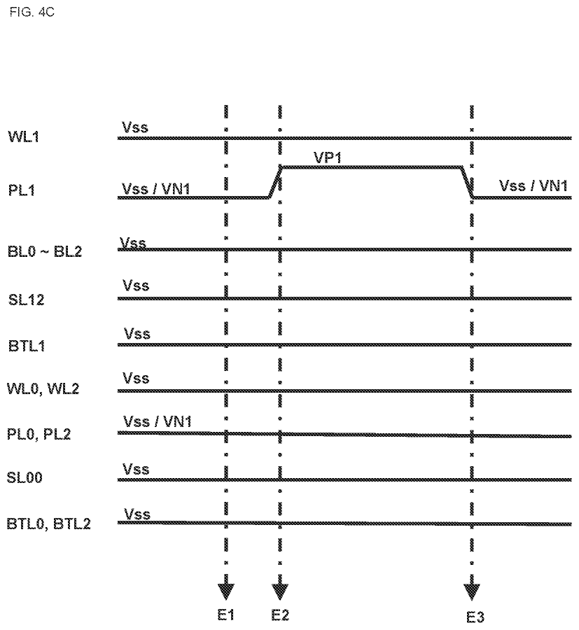

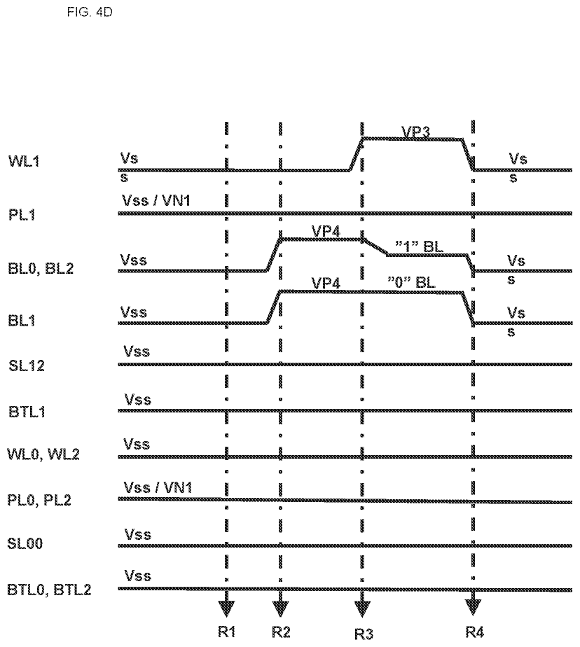

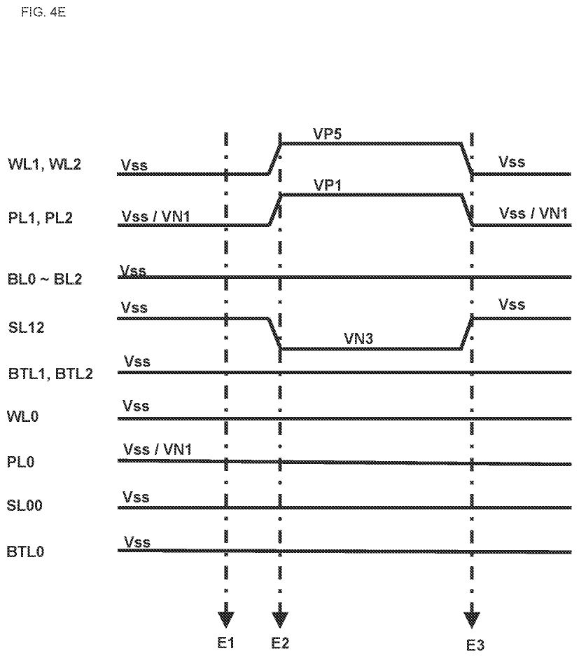

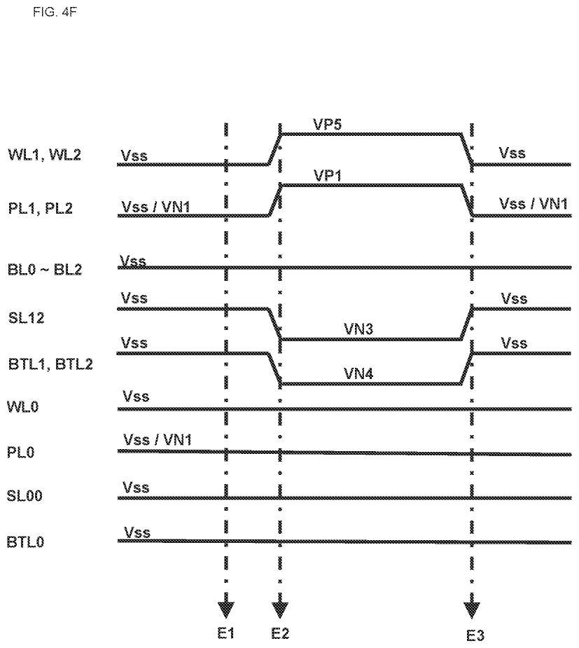

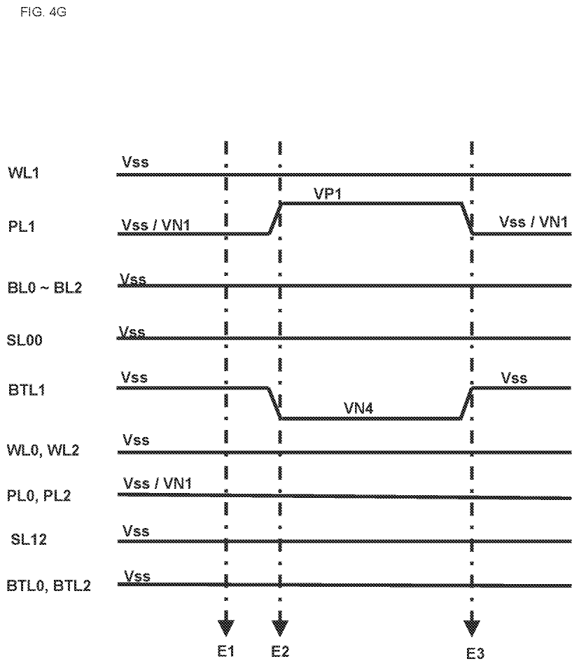

The page write operation, the page erase operation, and a page read operation of the dynamic flash memory according to the present embodiment will be described using FIGS. 4A to 4F.

A block diagram of a memory cell array (which is an example of a “memory cell array” described in Claims) including major circuits is shown in FIG. 4A. Word lines WL0 to WL2, plate lines PL0 to PL2, and source lines SL00 and SL12, are connected to a row decoder circuit RDEC. Bottom lines BTL0 to BTL2 are also connected to the row decoder circuit RDEC (a wiring diagram of connection is not shown). The row decoder circuit RDEC accepts row addresses RAD as input and selects pages P0 to P2 according to the row addresses RAD. The bit lines BL0 to BL2 intersect at right angles with the word lines WL0 to WL2, the plate lines PL0 to PL2, the source lines SL00 and SL12, and the bottom lines BTL0 to BTL2, and connects to a sense amplifier circuit SA. The sense amplifier circuit SA connects to a column decoder circuit CDEC, the column decoder circuit CDEC accepts column addresses CAD as input, and the sense amplifier circuit SA selectively connects to an input-output circuit IO according to the column addresses CAD.

In the memory cell array in FIG. 4A, one memory cell shown in an area surrounded by dashed lines corresponds to a memory cell shown in FIG. 1A and FIGS. 1BA to 1BC. That is, the second gate conductor layer 10 in FIG. 1A and FIGS. 1BA to 1BC is connected to the word line WL, the first gate conductor layer 22 is connected to the plate line PL, the second impurity layer, i.e., the n+ layer 7a, is connected to the source line SL, the third impurity layer, i.e., the n+ layer 7b, is connected to the bit line BL, and the first impurity layer, i.e., the n-layer 3, is connected to the bottom line BTL. Three rows by three columns for a total of nine memory cells C00 to C22 in planar view are shown here, but there are larger number of memory cells in actual memory arrays. When memory cells are arrayed in a matrix, one direction of the array is referred to as a “row direction” (or a “row-wise direction”) and a direction perpendicular to the row direction is referred to as a “column direction” (or a “column-wise direction”). In planar view, the source lines SL00 and SL12, the bottom lines BTL0 to BTL2, the plate lines PL0 to PL2, and the word lines WL0 to WL2 are disposed in parallel in the “row direction,” making up a plurality of pages. The bit lines BL0 to BL2 are disposed in a direction perpendicular to the row direction. For example, in this memory array, memory cells C10 to C12 connected with the plate line PL1, the word line WL1, the source line SL12, and the bottom line BTL1 of any page (which is an example of a “page” described in Claims) P1 are selected.

In FIG. 4A, those impurity layers of the memory cells C10 and C20 which correspond to the second impurity layer 7a shown in FIG. 1 are connected with each other by wiring. The memory cells C00 and C10 share an impurity layer that corresponds to the third impurity layer 7b shown in FIG. 1.

A page write operation will be described using an operation waveform diagram of FIG. 4B. At a first write time W1, voltage states of respective nodes are those that exist before the page write operation. A ground voltage Vss is applied to the word lines WL0 to WL2, the ground voltage Vss or a first negative voltage VN1 (which is an example of a “first negative voltage” described in Claims) is applied to the plate lines PL0 to PL2 as an applied voltage for data retention, the ground voltage Vss is applied to the bit lines BL0 to BL2, the ground voltage Vss is applied to the source lines SL00 and SL12, and the ground voltage Vss is applied to the bottom lines BTL0 to BTL2. The ground voltage Vss is, for example, 0 V and the first negative voltage VN1 is, for example, −1 V.

At a second write time W2, the word line WL1 on a page P1 is selected and the voltage falls from the ground voltage Vss to a second negative voltage VN2 (which is an example of a “second negative voltage” described in Claims). The second negative voltage VN2 is, for example, −1 V, which is equal to the first negative voltage VN1. At a third write time W3, assuming, based on write page data loaded into a sense amplifier circuit in advance, for example, that the bit lines BL0 and BL2 are used to write logical data of “1” and the bit line BL1 (subjected to page erasure in the previous cycle) is used to write logical data of “0”, the voltage of the bit lines BL0 and BL2 rises from the ground voltage Vss to a second positive voltage VP2 (which is an example of a “second positive voltage” described in Claims). As a result, a gate induced drain leakage current (GIDL) is generated by a high electric field between the second gate conductor layer 10 and the third impurity layer 7b of the memory cells C10 and C12, and the positive hole groups 11 are accumulated in the third semiconductor layer 8. Then, the logical data of “0” of the memory cells C10 and C12 is rewritten with logical data of “1”. At a fourth write time W4, the voltage of the word line WL1 that has been selected rises from the second negative voltage VN2 to the ground voltage Vss, and the voltage of the bit lines BL0 and BL2 falls from the second positive voltage VP2 to the ground voltage Vss, and the page write operation is finished.

A page erase operation will be described using an operation waveform diagram of FIG. 4C. At a first erase time E1, the voltage states of respective nodes are those that exist before the page erase operation. The ground voltage Vss is applied to the word lines WL0 to WL2, the ground voltage Vss or the first negative voltage VN1 is applied to the plate lines PL0 to PL2 as the applied voltage for data retention, the ground voltage Vss is applied to the bit lines BL0 to BL2, the ground voltage Vss is applied to the source lines SL00 and SL12, and the ground voltage Vss is applied to the bottom lines BTL0 to BTL2. The ground voltage Vss is, for example, 0 V and the first negative voltage VN1 is, for example, −1 V.

At a second erase time E2, the plate line PL1 on the page P1 is selected and the voltage rises from the ground voltage Vss or the first negative voltage VN1 to a first positive voltage VP1 (which is an example of a “first positive voltage” described in Claims). The first positive voltage VP1 is, for example, 2 V. At this time, since the voltages of the source line SL12 and the bit lines BL0 to BL2 have become equal to the ground voltage, as a result of capacitive coupling between the plate line PL1 and the second semiconductor layers 4 of the memory cells C10, C11, and C12 belonging to the page P1, the voltages of the second semiconductor layers 4 in a floating state rise. As a result, logical data of “1” has been written into the memory cells C10, C11, and C12 by the page write operation in the previous cycle and positive hole groups 11 have been accumulated in the second semiconductor layer 4 and the third semiconductor layer 8. The PN junctions involving the second impurity layer 7a, the third impurity layer 7b, the first impurity layer 3, the second semiconductor layer 4, and the third semiconductor layer 8 can be forward-biased, and positive hole groups 11 disappear. Even when the memory cells C10, C11, and C12 maintain logical data of “0” in the previous cycle, the remaining positive hole groups 11 disappear as well. That is, in all the memory cells C10, C11, and C12 belonging to the page P1, the page erase operation is performed and logical data of “0” is stored. At a third erase time E3, the voltage of the plate line PL1 that has been selected falls from the first positive voltage VP1 to the ground voltage Vss, and the page erase operation is finished.

A page read operation will be described using an operation waveform diagram of FIG. 4D. At a first read time R1, the voltage states of respective nodes are those that exist before the page read operation. The ground voltage Vss is applied to the word lines WL0 to WL2, the ground voltage Vss or the first negative voltage VN1 is applied to the plate lines PL0 to PL2 as the applied voltage for data retention, the ground voltage Vss is applied to the bit lines BL0 to BL2, the ground voltage Vss is applied to the source lines SL00 and SL12, and the ground voltage Vss is applied to the bottom lines BTL0 to BTL2. The ground voltage Vss is, for example, 0 V and the first negative voltage VN1 is, for example, −1 V.

At a second read time R2, the voltages of the bit lines BL0 to BL2 are raised by load transistor circuits (not illustrated) provided on the respective bit lines from the ground voltage Vss to a fourth positive voltage VP4 (which is an example of a “fourth positive voltage” described in Claims). At a third read time R3, the word line WL1 on the page P1 is selected and the voltage rises from the ground voltage Vss to a third positive voltage VP3 (which is an example of a “third positive voltage” described in Claims). The third positive voltage VP3 is, for example, 1.5 V. It is assumed here, for example, that stored data of the memory cells C10 and C12 is logical data of “1” and stored data of the memory cell C11 is logical data of “0”. As a result, in the memory cell C11 that stores logical data of “0”, because no memory cell current flows, the voltage of the bit line BL1 remains unchanged and the fourth positive voltage VP4 is maintained. On the other hand, in the memory cells C10 and C12 storing the logical data of “1”, a memory cell current flows. Thus, when the sense amplifier circuit SA is designed using a static current-sensing method, because the current values of the load transistor circuits and the current values of the memory cells counteract each other, the voltage of the bit lines BL0 and BL2 becomes equal to a voltage “1” BL lower than the voltage of the bit lines that read logical data of “0”. When the sense amplifier circuit SA is designed using a dynamic sensing method as in the case of DRAMs, the voltage of the bit lines BL0 and BL2 becomes equal to the ground voltage Vss. At a fourth read time R4, the voltage of the word line WL1 that has been selected falls from the third positive voltage VP3 to the ground voltage Vss, the voltage of the bit lines BL0 and BL2 falls from the voltage “1” BL used to read logical data of “0” to the ground voltage Vss, the voltage of the bit line BL1 falls from a voltage “0” BL, i.e., the fourth positive voltage VP4, used to read logical data of “0” to the ground voltage Vss, and the page read operation is finished.

In the page erase operation, as illustrated by an operation waveform diagram of FIG. 4E, at the second erase time E2, two pages, i.e., the pages P1 and P2, may be erased simultaneously by applying a third negative voltage VN3 (which is an example of a “third negative voltage” described in Claims) to the source line SL12. The third negative voltage VN3 is, for example, −0.7 V. In so doing, if a voltage of the word lines WL1 and WL2 is set to a fifth positive voltage VP5 (which is an example of a “fifth positive voltage” described in Claims), the erasure can be done more effectively. The fifth positive voltage VP5 is, for example, 1 V.

In the page erase operation, as illustrated by an operation waveform diagram of FIG. 4F, at the second erase time E2, two pages, i.e., the pages P1 and P2, may be erased simultaneously by applying a fourth negative voltage VN4 (which is an example of a “fourth negative voltage” described in Claims) to the bottom lines BTL1 and BTL2. The fourth negative voltage VN4 is, for example, −0.7 V. In so doing, if the third negative voltage VN3 is applied to the source line SL12 and the voltage of the word lines WL1 and WL2 is set to the fifth positive voltage VP5, the erasure can be done more effectively.

In the page erase operation, as illustrated by an operation waveform diagram of FIG. 4G, at the second erase time E2, a page erase operation for the page P1 may be performed by applying the fourth negative voltage VN4 to the bottom line BTL1. Consequently, a single-page erase operation becomes possible.

The present embodiment has the following features.

### (Feature 1)

In a page write operation period, by controlling voltages applied to the source line SL, the bit line BL, the word line WL, the plate line PL, and the bottom line BTL, the dynamic flash memory according to the first embodiment of the present invention performs a write operation of holding positive hole groups in the vicinity of the gate insulating layer, the positive hole groups having been generated in a channel region of the third semiconductor layer 8 by a gate induced drain leakage current (GIDL), and an erase operation of removing the positive hole groups. Possible operation mechanisms of writing data into memory cells includes a write operation that uses the positive hole groups 11 from electron-hole pairs generated by an impact ionization phenomenon that involves causing an electron stream to flow from source to drain and causing electron groups having high kinetic energy to collide with a silicon lattice in the vicinity of the drain. This operation mechanism requires the electron stream flowing from source to drain to serve as a trigger current in triggering impact ionization. This requires a large amount of current. This in turn increases the power consumption of the write operation. In contrast, by performing a data write operation using the gate induced drain leakage current (GIDL) in the page write operation period, a write current can be reduced greatly.

### (Feature 2)

For impact ionization phenomenon, not only the electron stream flowing from source to drain to serve as a trigger current, but also a sufficient channel length is required in order to obtain the kinetic energy of the electron stream. For example, with a NOR-type flash memory that writes “1” data using the impact ionization phenomenon, an effective channel length Leff of at least 45 nm is required, which obstructs scaling of the NOR-type flash memory. On the other hand, when the gate induced drain leakage current (GIDL) is used as a mechanism of writing data into memory cells, by controlling the electric field between the second gate conductor layer 10 and the third impurity layer 7b and thereby generating the gate induced drain leakage current (GIDL), it is possible to easily generate positive hole groups 11 for data writing. As a result, regardless of Leff that controls memory cell scaling, memory cells that lend themselves to scaling can be developed. This makes it possible to provide a densely-packed, low-power, dynamic flash memory. This leads to cost reduction of the dynamic flash memory.

### (Feature 3)

The use of the gate induced drain leakage current makes it possible to reduce the DC current between the bit line and the source line to zero in the page write operation. This in turn makes it possible greatly reduce power consumption during data writing and write data into multi-bit memory cells simultaneously. Consequently, it is possible to provide a low-power, high-speed dynamic flash memory.

### (Feature 4)

In the page erase operation, capacitive coupling between the first gate conductor layer 22 and the second semiconductor layer 4 allows the voltage of the second semiconductor layer 4 to be boosted. As a result, the PN junctions involving the second impurity layer 7a, the third impurity layer 7b, the first impurity layer 3, the second semiconductor layer 4, and the third semiconductor layer 8 can be forward-biased. Consequently, in memory cells written with logical data of “1” by a page write operation, the positive hole groups 11 accumulated in the second semiconductor layer 4 and the third semiconductor layer 8 can be caused to disappear effectively.

### (Feature 5)

In the dynamic flash memory according to the first embodiment of the present invention, a substrate area on which a MOSFET channel is formed is made up of the p-layer 4 and the p-layer 8 surrounded by the insulating layer 2, the gate insulating layer 5, and the n-layer 3. This structure makes it possible to accumulate the majority carriers generated in writing logic “1” in the p-layer 8 and the p-layer 4 and increase the number of majority carriers. Furthermore, because the positive holes generated during writing can be accumulated near the interface of the p-layer 4 in the vicinity of the gate conductor layer 22 and information retention time is extended. During data erasure, as an inversion layer is formed by the application of a positive voltage to the gate conductor layer 22, effectively increasing the electron-hole recombination area, the area of recombination with electrons is increased and the erasure is done in a short time. Furthermore, when a negative voltage is applied to the n+ layer 7a connected to the source line SL, a thyristor structure of the n+ layer 7a, the p-layer 8, the p-layer 4, the n-layer 3, and the p-layer 1 can accelerate the erase operation. This makes it possible to expand the operating margin of the memory and reduce power consumption, resulting in high-speed operation of the memory.

### (Feature 6)

The p-layer 8, which is a component of the MOSFET contained in the dynamic flash memory according to the first embodiment of the present invention, is connected with the p-layer 4, the n-layer 3, and the p-layer 1, and if the voltage applied to the gate conductor layer 22 is adjusted, the p-layer 8 and the p-layer 4 under the gate insulating layer 9 are not completely depleted. Consequently, the threshold, drive current, and the like of the MOSFET are hardly affected by the operational status of the memory. Furthermore, since the components under the MOSFET are not completely depleted, coupling of a word line in a floating state to a gate electrode, which is a defect of capacitorless DRAMs, almost does not have a significant impact. That is, the present invention allows a wide margin to be provided to the operating voltage of the dynamic flash memory.

A dynamic flash memory element has been described in FIGS. 1A to 1BC by taking as an example the SGT that includes the first gate insulating layer 5 and the first gate conductor layer 22, where the first gate insulating layer 5 surrounds the entire lateral surface of the second semiconductor layer 4 erected in the vertical direction on the substrate. As indicated in the description of the present embodiment, it is sufficient if the present dynamic flash memory element is structured to satisfy the condition that the positive hole groups 11 generated by a gate induced drain leakage current are held in the second semiconductor layer 4 and the third semiconductor layer 8. For that, it is sufficient if the second semiconductor layer 4 and the third semiconductor layer 8 has a floating body structure electrically separated from the substrate 20. Consequently, even if semiconductor base bodies of the second semiconductor layer 4 and the third semiconductor layer 8 are formed horizontally to the substrate 20 (such that center axes of the semiconductor base bodies will be horizontal to the substrate), using, for example, GAA (gate all around) technology or nanosheet technology, which are types of SGT technology, the dynamic flash memory operation can be performed. Alternatively, a plurality of GAA transistors or nanosheet transistors formed in the horizontal direction may be stacked one on top of another. A device structure based on SOI (silicon on insulator) may also be used. In this device structure, a bottom of the channel region is in contact with an insulating layer of an SOI substrate and surrounds other channel regions while being surrounded by a gate insulating layer and an element-separating insulating layer. In this structure, again the channel region has a floating body structure. In this way, it is sufficient if the dynamic flash memory element provided by the present embodiment satisfies the condition that the channel region has a floating body structure. Even with a structure in which a Fin transistor is formed on an SOI substrate, the present dynamic flash memory operation can be performed as long as the channel region has a floating body structure.

The present invention can be embodied or modified in various forms without departing from the spirit and scope of the present invention in a broad sense. Also, the embodiment described above is meant to be illustrative, and not to limit the scope of the present invention. The embodiment and variations described above can be combined as desired. Furthermore, even if some components of the embodiment described above are removed as required, the resulting embodiment fall within the scope of the technical idea of the present invention.

### INDUSTRIAL APPLICABILITY

The use of the memory device that uses a semiconductor element according to the present invention provides a high-speed dynamic flash memory longer in storage time and lower in power consumption than conventional devices.

What is claimed is:

1. A memory device that uses a semiconductor element, in which a page is made up of a plurality of memory cells arranged in a row direction on a substrate in planar view, the plurality of memory cells are connected to a bit line disposed in a column direction, a memory cell array is made up of a plurality of the pages and a plurality of the bit lines, and the memory device is made up of at least one memory cell array, wherein:
each of the memory cells contained in the respective pages includes:
the substrate,
a first semiconductor layer placed on the substrate,
a first impurity layer placed on part of a surface of the first semiconductor layer, at least part of the first impurity layer being columnar in shape,
a second semiconductor layer extending in a vertical direction by being placed in contact with a columnar part of the first impurity layer,
a first insulating layer covering part of the first semiconductor layer and part of the first impurity layer,
a first gate insulating layer surrounding the first impurity layer and the second semiconductor layer by being placed in contact with the first insulating layer,
a first gate conductor layer placed in contact with the first insulating layer and the first gate insulating layer,
a second insulating layer formed in contact with the first gate conductor layer and the first gate insulating layer,
a third semiconductor layer placed in contact with the second semiconductor layer,
a second gate insulating layer partially or entirely surrounding an upper part of the third semiconductor layer,
a second gate conductor layer partially or entirely covering an upper part of the second gate insulating layer, and
a second impurity layer and a third impurity layer placed, respectively, in contact with opposing lateral surfaces of the third semiconductor layer located on an outer side of one end of the second gate conductor layer in a horizontal direction in which the third semiconductor layer extends;
the second impurity layer is connected with a source line, the third impurity layer is connected with a bit line, the second gate conductor layer is connected with a word line, and the first gate conductor layer is connected with a plate line;
a page erase operation, a page write operation, and a page read operation are performed by controlling voltages applied to the source line, the bit line, the word line, and the plate line;
the page erase operation involves extracting electron groups or positive hole groups whichever are majority carriers remaining in the second semiconductor layer or the third semiconductor layer by recombining the electron groups or the positive hole groups with majority carriers in the first impurity layer, the second impurity layer, and the third impurity layer;
the page write operation involves an operation of generating the electron groups and the positive hole groups in the third semiconductor layer and the second semiconductor layer using a gate induced drain leakage current, an operation of removing the generated electron groups or the positive hole groups whichever are minority carriers in the third semiconductor layer and the second semiconductor layer, and an operation of causing part or all of the electron groups or the positive hole groups whichever are majority carriers in the third semiconductor layer and the second semiconductor layer to remain in the third semiconductor layer and the second semiconductor layer; and
the page read operation involves determining whether the memory cell is in an erased state or a written state based on a magnitude relationship between memory cell currents flowing through the bit line and the source line of the memory cell.

2. The memory device that uses a semiconductor element according to claim 1, wherein the majority carriers in the third semiconductor layer and the second semiconductor layer are the positive hole groups, and the number of positive holes in the positive hole groups is larger in the written state than in the erased state.

3. The memory device that uses a semiconductor element according to claim 1, wherein the erased state is logical data of “0” and the written state is logical data of “1,” and the memory cell currents are larger for the logical data of “1” than for the logical data of “0” by an order of magnitude or more.

4. The memory device that uses a semiconductor element according to claim 1, wherein during data retention in the memory cell, a ground voltage or a first negative voltage is applied to the plate line.

5. The memory device that uses a semiconductor element according to claim 4, wherein during the data retention in the memory cell, the ground voltage is applied to the source line, the bit line, and the word line.

6. The memory device that uses a semiconductor element according to claim 1, wherein in the page erase operation, a first positive voltage is applied to the plate line.

7. The memory device that uses a semiconductor element according to claim 1, wherein in the page write operation, a second negative voltage is applied to the word line.

8. The memory device that uses a semiconductor element according to claim 1, wherein in the page write operation, a second positive voltage is applied to the bit line.

9. The memory device that uses a semiconductor element according to claim 1, wherein in the page read operation a third positive voltage is applied to the word line and a fourth positive voltage is applied to the bit line.

10. The memory device that uses a semiconductor element according to claim 1, wherein a vertical distance from a bottom of the third semiconductor layer to an upper part of the first impurity layer is shorter than a vertical distance from the bottom of the third semiconductor layer to a bottom of the first gate conductor layer.

11. The memory device that uses a semiconductor element according to claim 1, wherein the source line joined to the second impurity layer of the memory cell is shared with an impurity layer corresponding to the second impurity layer of an adjacent one of the memory cells.

12. The memory device that uses a semiconductor element according to claim 1, wherein the bit line joined to the third impurity layer of the memory cell is shared with an impurity layer corresponding to the third impurity layer of an adjacent one of the memory cells.

13. The memory device that uses a semiconductor element according to claim 1, wherein a first negative voltage is applied to the plate line during data retention in the memory cell, a second negative voltage is applied to the word line in the page write operation, and the first negative voltage and the second negative voltage are equal in value.

14. The memory device that uses a semiconductor element according to claim 4, wherein the ground voltage is zero volts.

15. The memory device that uses a semiconductor element according to claim 1, wherein a bottom of the first impurity layer is located deeper than a bottom of the first insulating layer, and the first impurity layer is shared by the plurality of memory cells.

16. The memory device that uses a semiconductor element according to claim 1, wherein a bottom line is joined to the first impurity layer and a desired voltage is able to be applied to the bottom line.

17. The memory device that uses a semiconductor element according to claim 1, wherein in the page erase operation, a third negative voltage is applied to the source line and a fifth positive voltage is applied to the word line.

18. The memory device that uses a semiconductor element according to claim 16, wherein in the page erase operation, a fourth negative voltage is applied to the bottom line.

19. The memory device that uses a semiconductor element according to claim 16, wherein the source line, the word line, the plate line, and the bottom line are disposed in parallel in the row direction, making up the page, and the bit line disposed in the column direction is orthogonal to the page.

20. The memory device that uses a semiconductor element according to claim 1, wherein in the page write operation, a DC current between the bit line and the source line is zero.

21. The memory device that uses a semiconductor element according to claim 1, wherein in the page erase operation, a voltage of the second semiconductor layer is boosted by capacitive coupling between the first gate conductor layer and the second semiconductor layer.
